(19) United States
(12) Patent Application Publication
(10) Pub. No.: US 2026/0230047 A1
(43) Pub. Date: Aug. 6, 2026

(54) COMPOSITE AMPLIFIER CORE, AMPLIFIER STRUCTURE, AND CIRCUIT STRUCTURE FORMED THEREOF

(71) Applicant: ARGUS SPACE AG, Erlenbach (CH)

(72) Inventors: Hua WANG, Zurich (CH); Tzu-Yuan HUANG, Zurich (CH)

(73) Assignee: ARGUS SPACE AG, Erlenbach (CH)

(21) Appl. No.: 19/570,973

(22) Filed: Mar. 18, 2026

Related U.S. Application Data
(63) Continuation of application No. PCT/US2024/047563, filed on Sep. 19, 2024.
(60) Provisional application No. 63/539,302, filed on Sep. 19, 2023.

(51) Int. Cl. H03F 3/24

(52) U.S. Cl. CPC H03F 3/245; H03F 2200/451

(57) ABSTRACT

In certain aspects, a composite amplifier core, an amplifier structure, and a circuit structure formed thereof are provided. The composite amplifier core includes one or more first basic amplifiers of a first type and one or more second basic amplifiers of a second type. The amplifier structure includes the composite amplifier core. The amplifier structure further includes one or more coupling networks including at least one of an input coupling network, an output coupling network, or an inter-stage coupling network within the composite amplifier structure. The one or more coupling networks are couple to each other. A sizing ratio between the one or more first basic amplifiers and the one or more second basic amplifiers in the composite amplifier core is adjustable.

### CROSS-REFERENCE TO RELATED APPLICATIONS

This application is a continuation of International Application No. PCT/US2024/047563, filed September 19, 2024, which is based upon and claims priority to U.S. Provisional Application No. 63/539,302, filed September 19, 2023. The entire contents of each of the above-referenced applications are expressly incorporated herein by reference.

### BACKGROUND

The present disclosure relates to circuit design, and more particularly to, circuit design of amplifiers having composite amplifier cores and coupling networks.

An amplifier is an electronic device that increases the voltage, current, or power of a signal. A basic amplifier core topology may include a common-source (CS) amplifier, a common-gate (CG) amplifier, or a common-drain (CD) amplifier. Some example amplifiers are designed with the single use of the common-source amplifier core topology, the common-drain amplifier core topology, or the common-gate amplifier core topology, resulting in limited performance and often tight tradeoffs between different performance metrics.

### SUMMARY

In one aspect, a composite amplifier core is disclosed. The composite amplifier core includes one or more first basic amplifiers of a first type and one or more second basic amplifiers of a second type. A sizing ratio between the one or more first basic amplifiers and the one or more second basic amplifiers in the composite amplifier core is adjustable.

In another aspect, an amplifier structure is disclosed. The amplifier structure includes a composite amplifier core. The composite amplifier core includes one or more first basic amplifiers of a first type and one or more second basic amplifiers of a second type. A sizing ratio between the one or more first basic amplifiers and the one or more second basic amplifiers in the composite amplifier core is adjustable. The amplifier structure further includes an input coupling network connected to the composite amplifier core and configured to provide input signals to the composite amplifier core. The amplifier structure further includes an output coupling network connected to the composite amplifier core and configured to generate or provide the output signals of the composite amplifier core. The amplifier structure further includes an inter-stage coupling network within the composite amplifier core, which can be coupled to the input coupling network and/or the output coupling network.

In still another aspect, a circuit structure is disclosed. The circuit structure includes a first amplifier structure and a second amplifier structure cascaded with the first amplifier structure. Each of the first amplifier structure and the second amplifier structure includes a composite amplifier core, an input coupling network connected to the composite amplifier core and configured to provide input signals to the composite amplifier core, an output coupling network connected to the composite amplifier core and configured to adjust and provide output signals of the composite amplifier core, and an interstage coupling network within the composite amplifier core that can be coupled to the input coupling network and/or the output coupling network. The composite amplifier core includes one or more first basic amplifiers of a first type and one or more second basic amplifiers of a second type. A sizing ratio between the one or more first basic amplifiers and the one or more second basic amplifiers in the composite amplifier core is adjustable.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1A illustrates an example amplifier topology, according to some examples of the present disclosure.

FIG. 1B illustrates Common-Source(CS)/common-Emitter(CE) amplifiers, according to some examples of the present disclosure.

FIG. 1C illustrates Common-Gate(CG)/common-Base(CB) amplifiers, according to some examples of the present disclosure.

FIG. 2A illustrates example basic amplifiers, according to some aspects of the present disclosure.

FIGS. 2B and 2C illustrate example composite amplifier cores, according to some aspects of the present disclosure.

FIG. 3A illustrates an amplifier structure including a composite amplifier core, according to some aspects of the present disclosure.

FIG. 3B illustrates an amplifier structure including a composite amplifier core with CS amplifiers and CG amplifiers, according to some aspects of the present disclosure.

FIG. 3C illustrates a detailed schematic diagram of the amplifier structure of FIG. 3B, according to some aspects of the present disclosure.

FIG. 3D illustrates an amplifier structure including a composite amplifier core in a single-ended cascode configuration, according to some aspects of the present disclosure.

FIG. 3E illustrates an amplifier structure including a composite amplifier core in a differential cascode configuration, according to some aspects of the present disclosure.

FIG. 3F illustrates an amplifier structure including a composite amplifier core in a differential cascode configuration with output feedback, according to some aspects of the present disclosure.

FIG. 3G illustrates an amplifier structure including a composite amplifier core in a differential cascode configuration with coupling between an input coupling network and an inter-stage coupling network, according to some aspects of the present disclosure.

FIG. 3H illustrates an amplifier structure including a composite amplifier core in a differential cascode configuration with coupling between an input coupling network and an inter-stage coupling network and coupling between the inter-stage coupling network and an output coupling network, according to some aspects of the present disclosure.

FIG. 4 illustrates a circuit structure including amplifier structures, according to some aspects of the present disclosure.

FIG. 5 illustrates a circuit structure used in RF/mm-Wave system applications, according to some aspects of the present disclosure.

FIGS. 6A-6H illustrate simulation on an example common-source power amplifier, according to some examples of the present disclosure.

FIGS. 7A-7I illustrate simulation on a power amplifier having an amplifier structure of FIG. 3A, according to some aspects of the present disclosure.

FIG. 8A illustrates a load pull simulation of a cascode amplifier core at 39GHz, according to some examples of the present disclosure.

FIG. 8B illustrates a load pull simulation of a composite amplifier core at 39GHz, according to some aspects of the present disclosure.

FIG. 9A illustrates a continuous wave simulation of a composite amplifier core at 39GHz, according to some aspects of the present disclosure.

FIG. 9B illustrates a continuous wave simulation of a composite amplifier core at 39GHz under a voltage-standing-wave-ratio (VSWR) of 3-to-1, according to some aspects of the present disclosure.

FIG. 9C illustrates a continuous wave simulation of a common source amplifier core at 39GHz, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

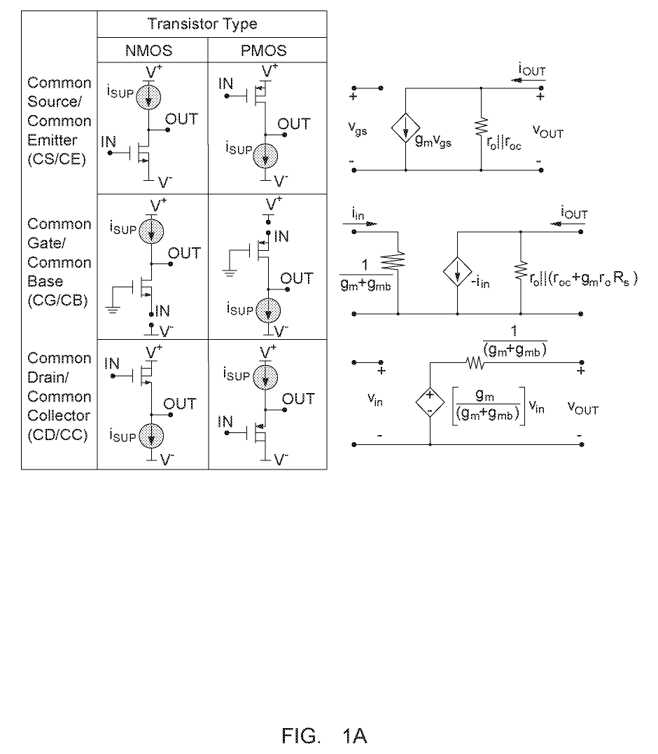

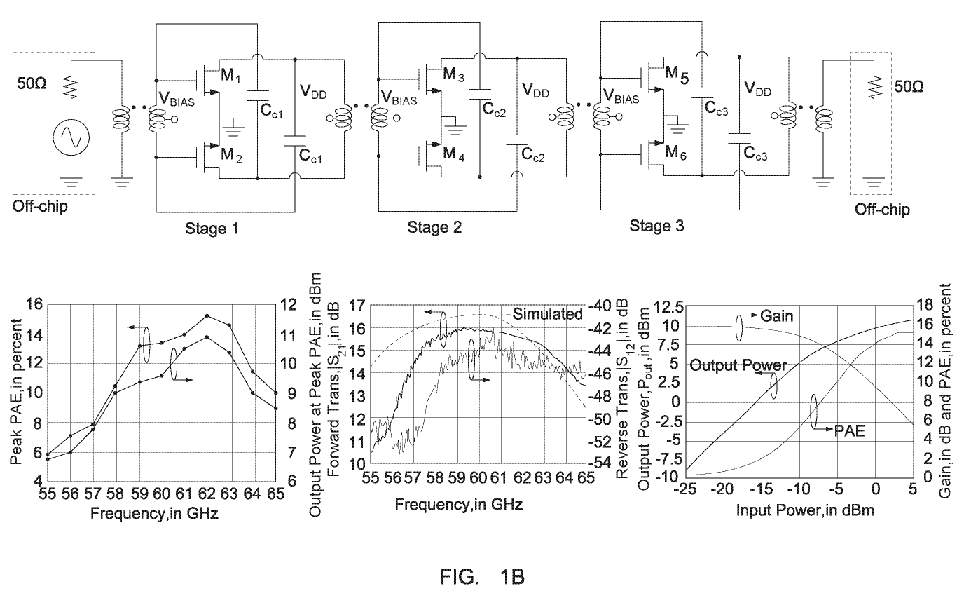

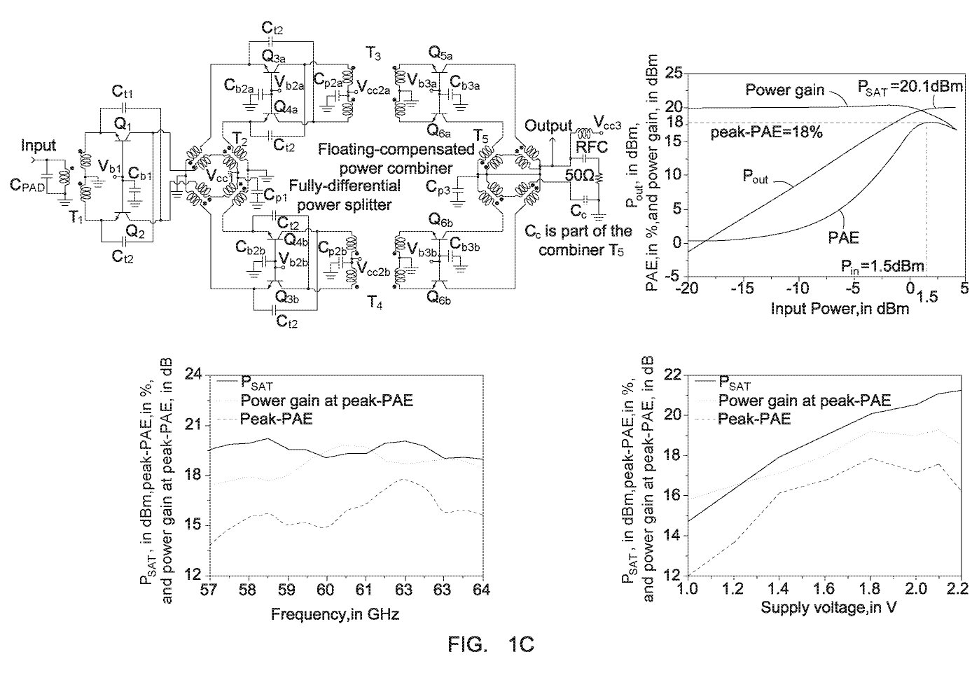

FIG. 1A illustrates an example amplifier topology. FIG. 1B illustrates that common-source(CS)/common-emitter(CE) amplifiers can deliver high gain and high power (saturation output power) with high energy efficiency. FIG. 1C illustrates that common-gate(CG)/common-base(CB) amplifiers can deliver high linear output power (OP1dB#) with limited gain, where OP1dB# denotes the output power level at which the gain decreases 1 dB from its constant value.

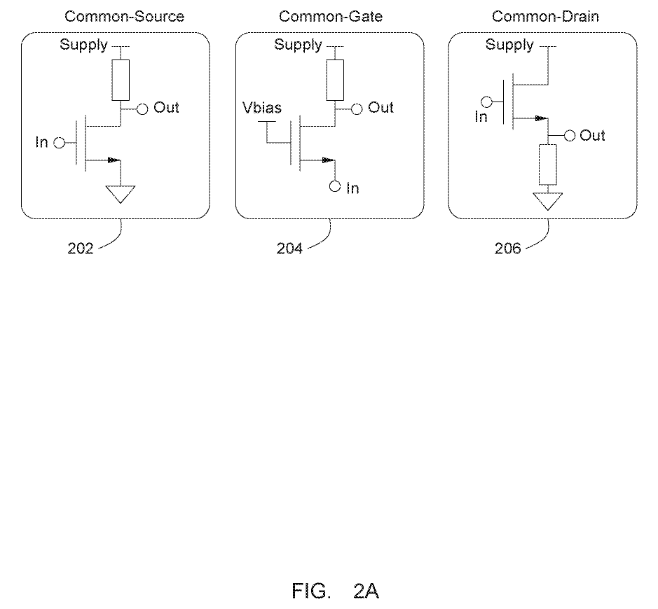

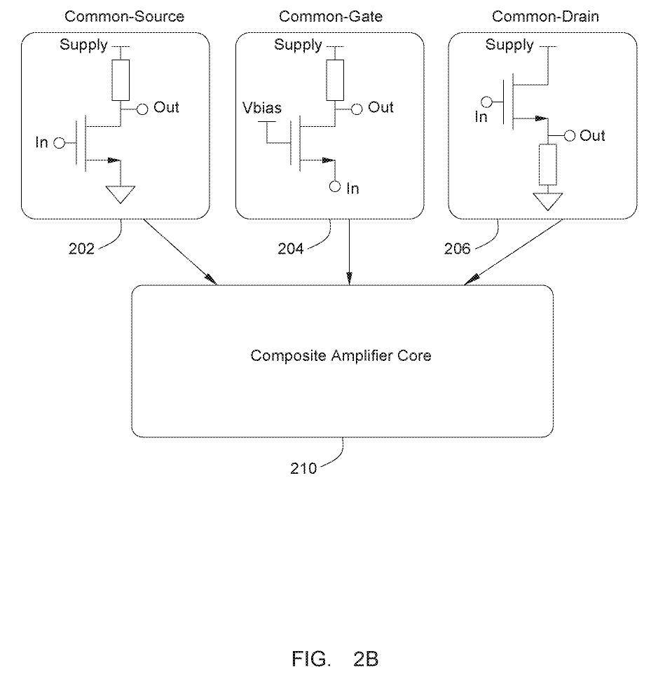

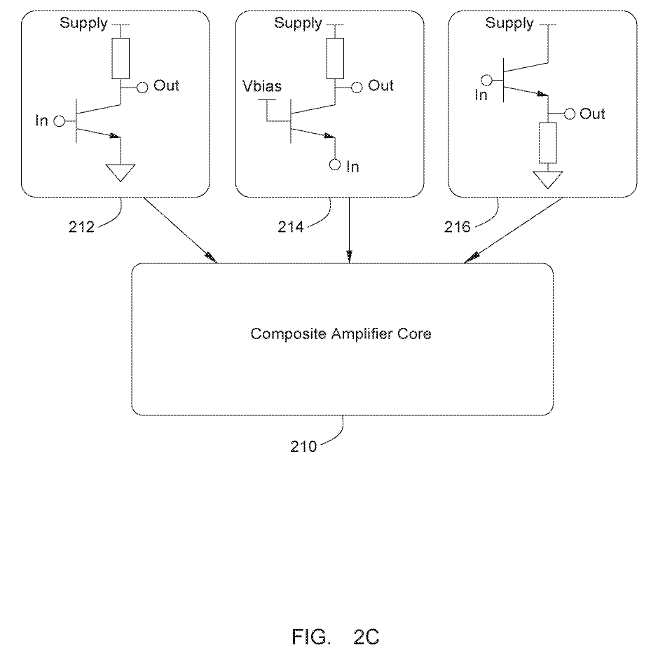

FIG. 2A illustrates example basic amplifiers such as a common-source (CS) amplifier 202, a common-gate (CG) amplifier 204, and a common-drain (CD) amplifier 206. Most example amplifier active cores are designed with the single use of the common-source amplifier core topology, the common-drain amplifier core topology, or the common-gate amplifier core topology, resulting in their limited performance and often tight tradeoffs between different performance metrics. Consistent with some aspects of the present disclosure, a composite amplifier core disclosed herein combines two or more different types of basic amplifiers (e.g., two or more of the common-source amplifier core topology, the common-drain amplifier core topology, and the common-gate amplifier core topology) to harvest the benefits of the different types of basic amplifiers. For example, the composite amplifier core may form a hybrid circuit by selectively using and coupling two or more cores of the basic amplifiers together to harvest their benefits and outperform any of these basic amplifiers.

In some implementations, the basic amplifiers in the composite amplifier core disclosed herein can be connected in parallel or in series. Alternatively or additionally, the basic amplifiers in the composite amplifier core disclosed herein can be connected in a cascode configuration. Alternatively or additionally, the basic amplifiers in the composite amplifier core disclosed herein can be in either single-ended or differential configurations.

FIG. 2B illustrates a composite amplifier core 210 (also referred to as composite device core or composite active core) which may include two or more of the following basic amplifiers: CS amplifier 202, CG amplifier 204, or CD amplifier 206. CS amplifier 202, CG amplifier 204, and CD amplifier 206 are MOSFET or MESFET types of circuits. It is understood that for circuits based on bipolar junction transistors (BJTs), the corresponding basic amplifiers included in composite amplifier core 210 can include two or more of a common-emitter (CE) amplifier 212, a common-base (CB) amplifier 214, or a common-collector (CC) amplifier 216, as shown in FIG. 2C. It is also understood that the corresponding basic amplifiers included in composite amplifier core 210 can also be amplifiers based on GaN, GaAs, etc., which is not limited herein.

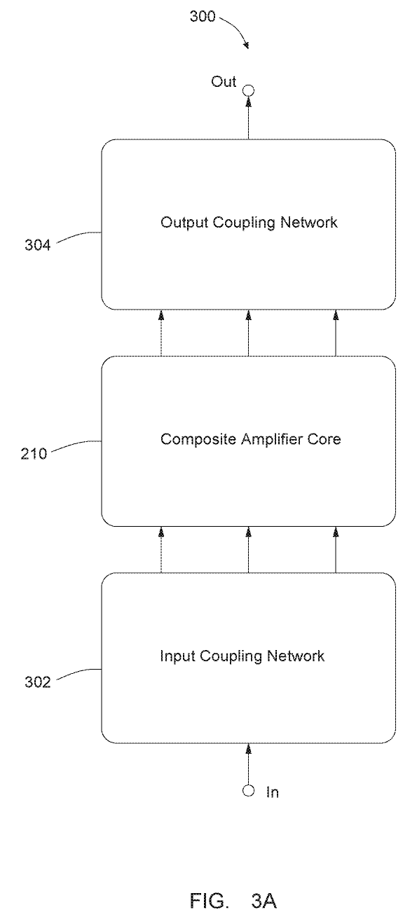

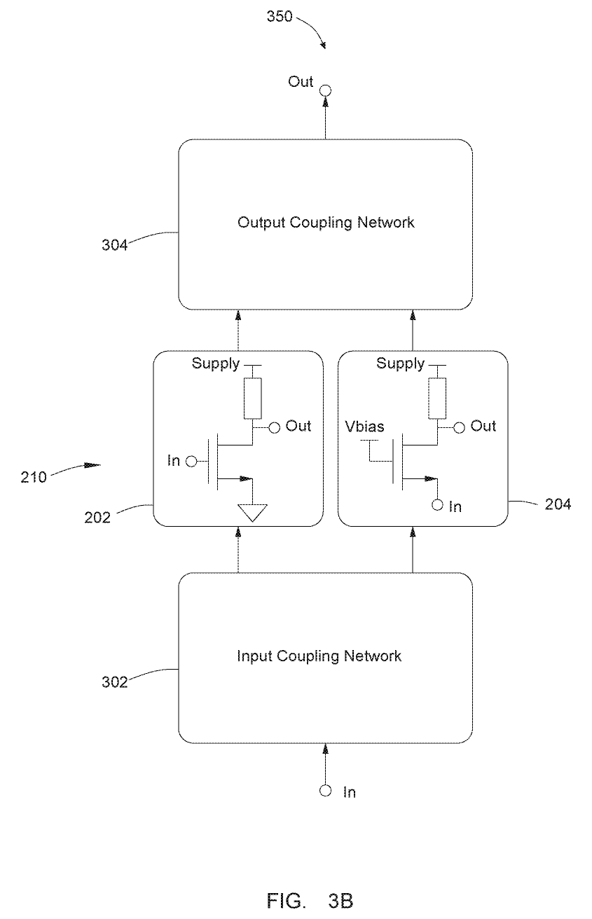

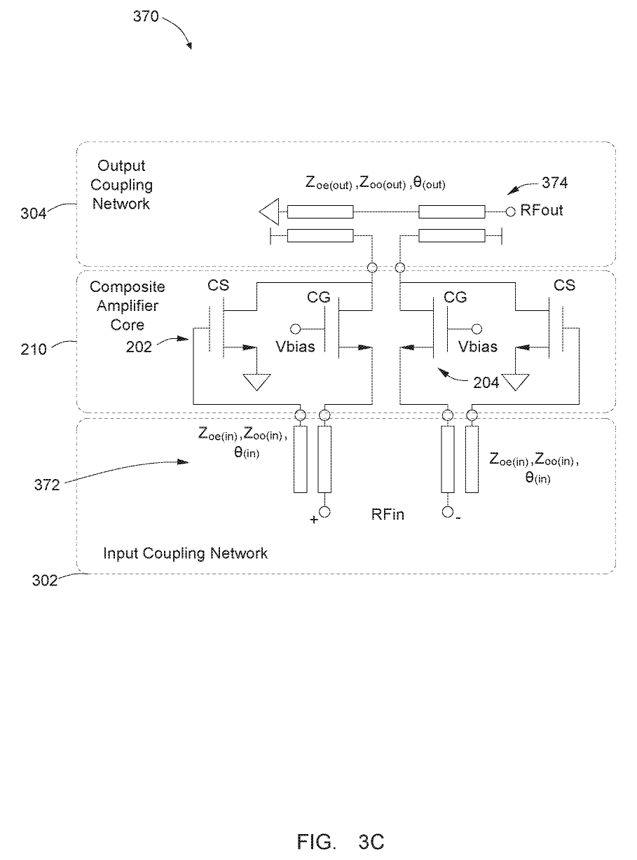

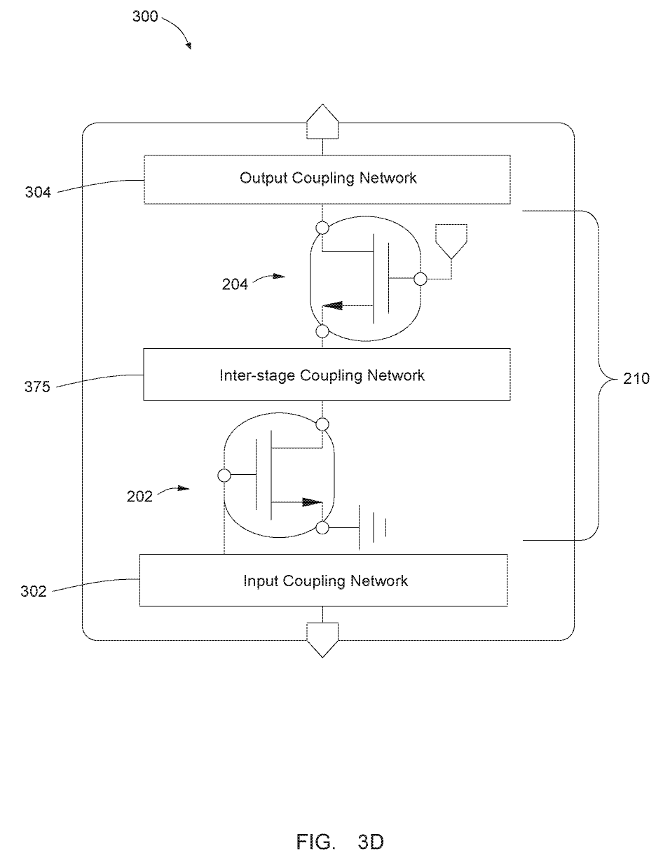

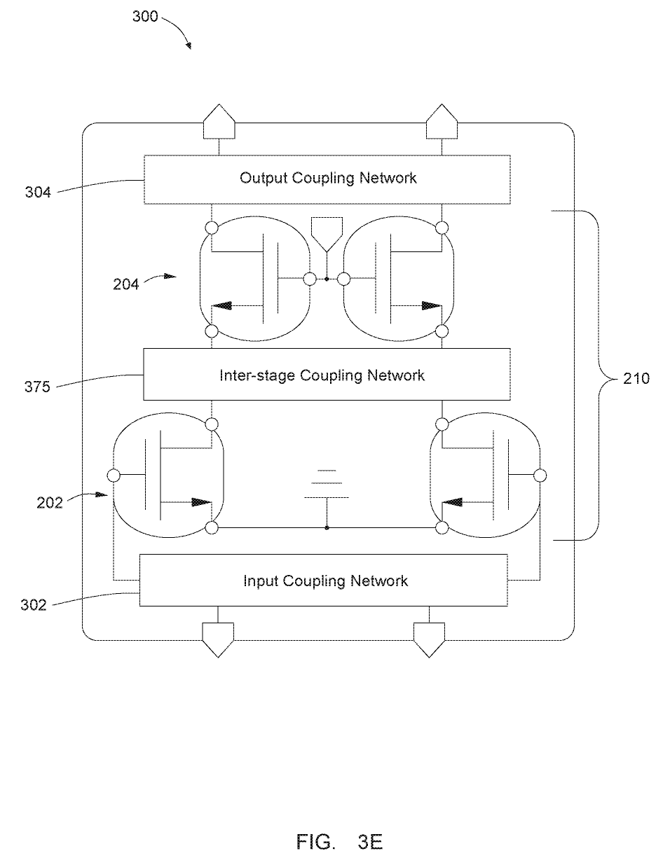

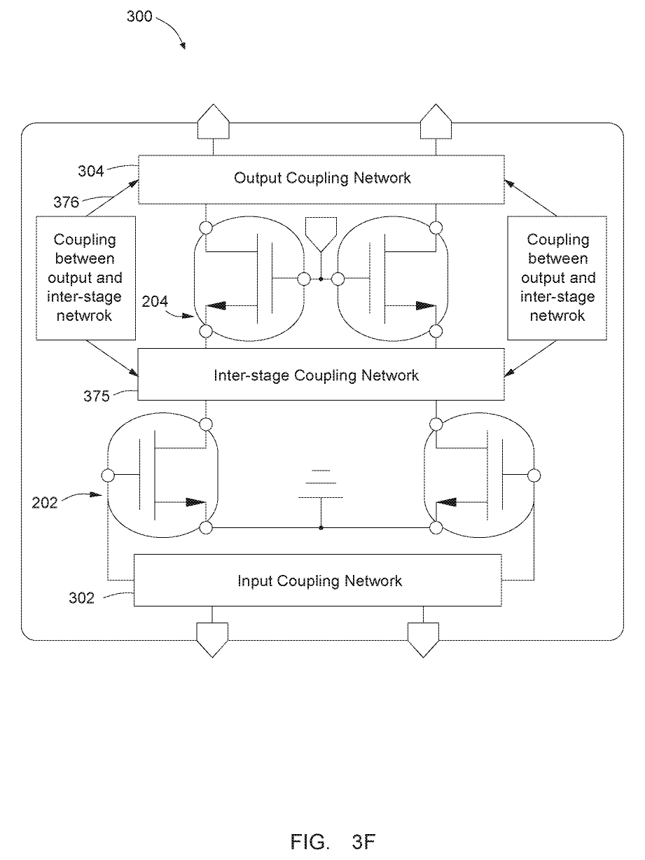

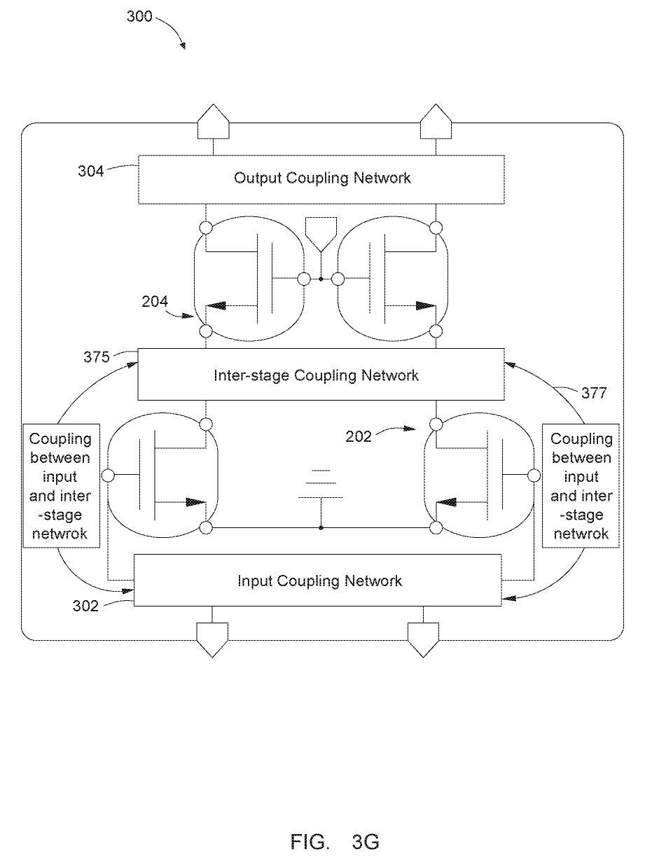

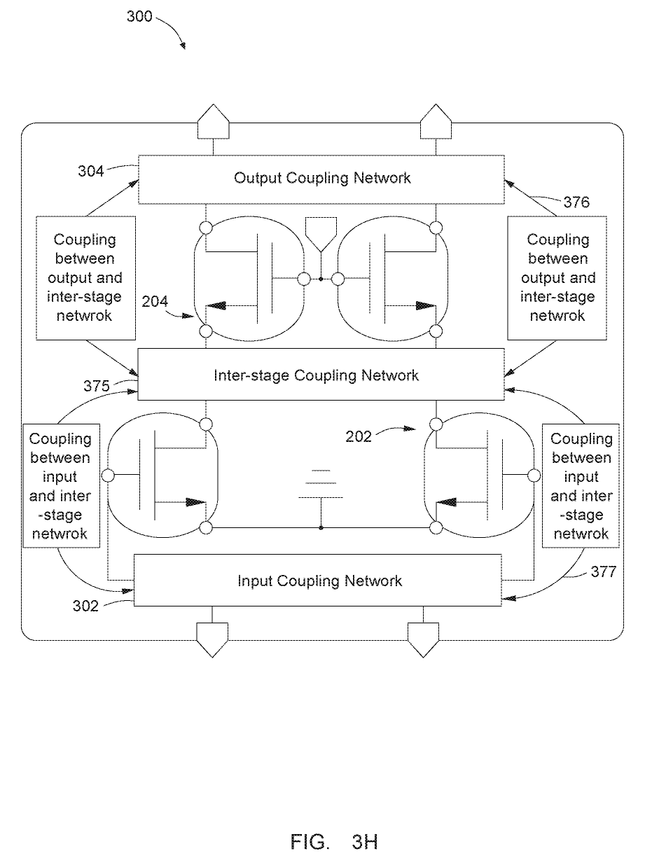

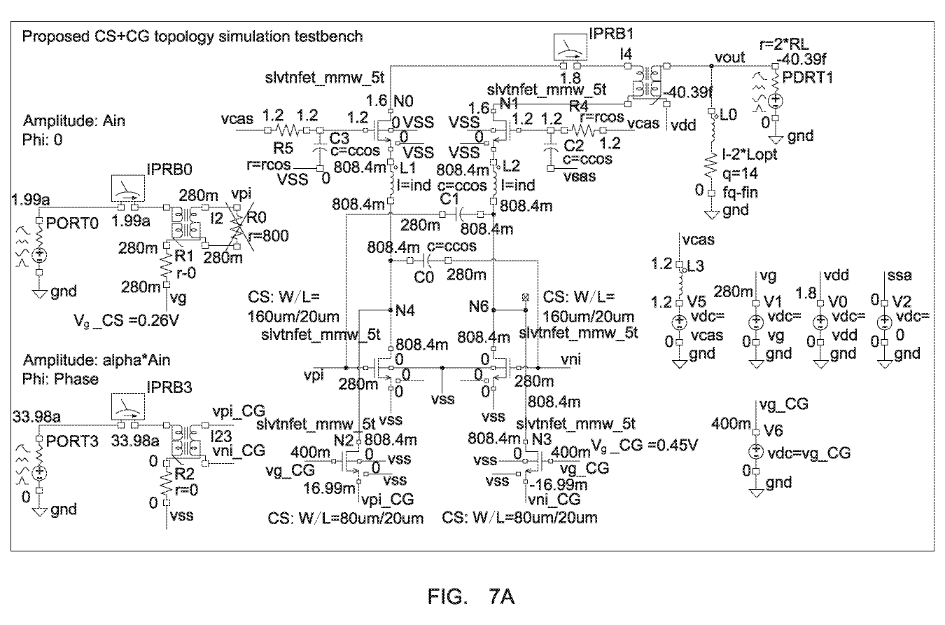

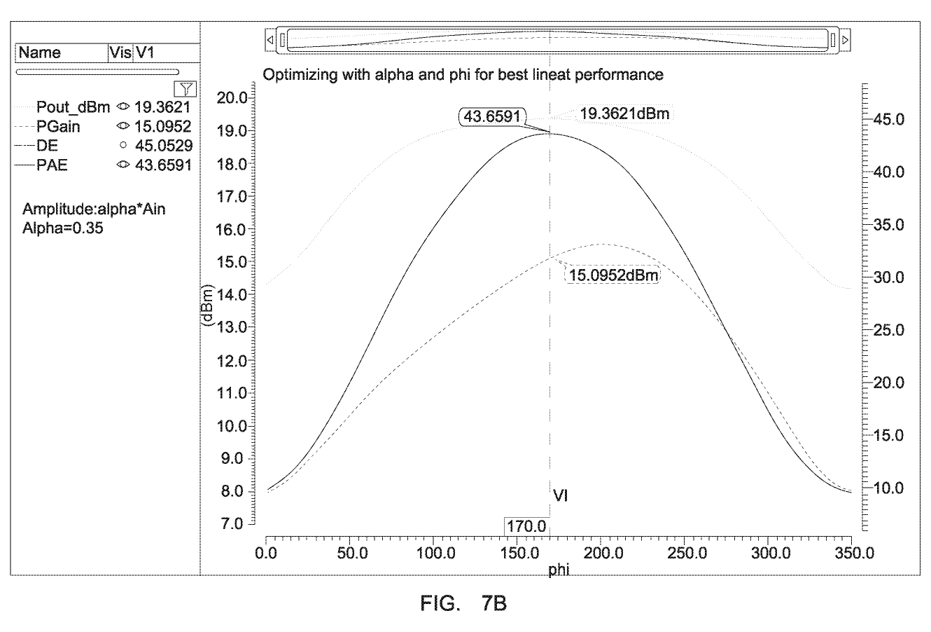

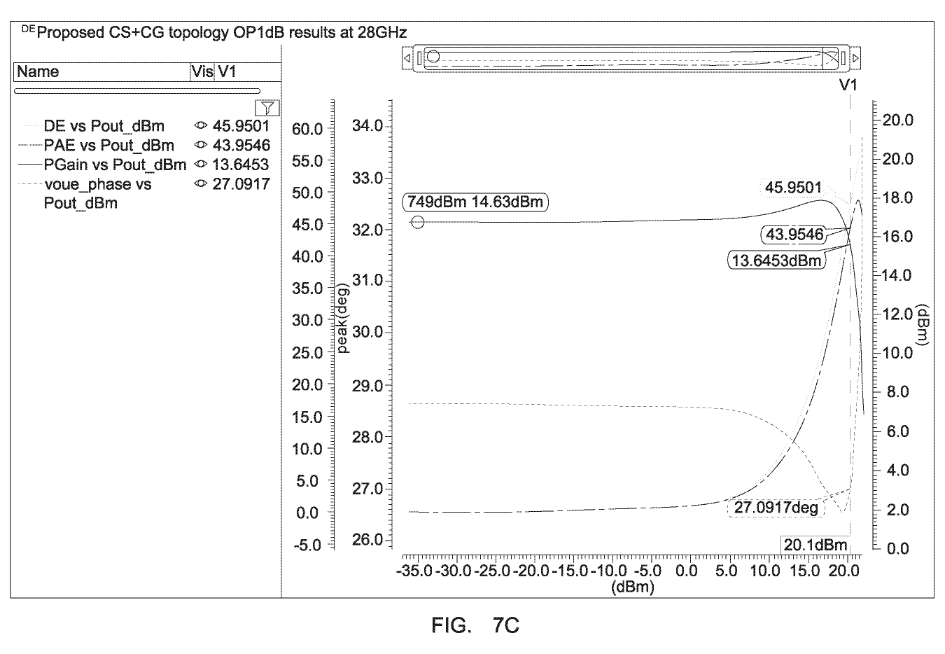

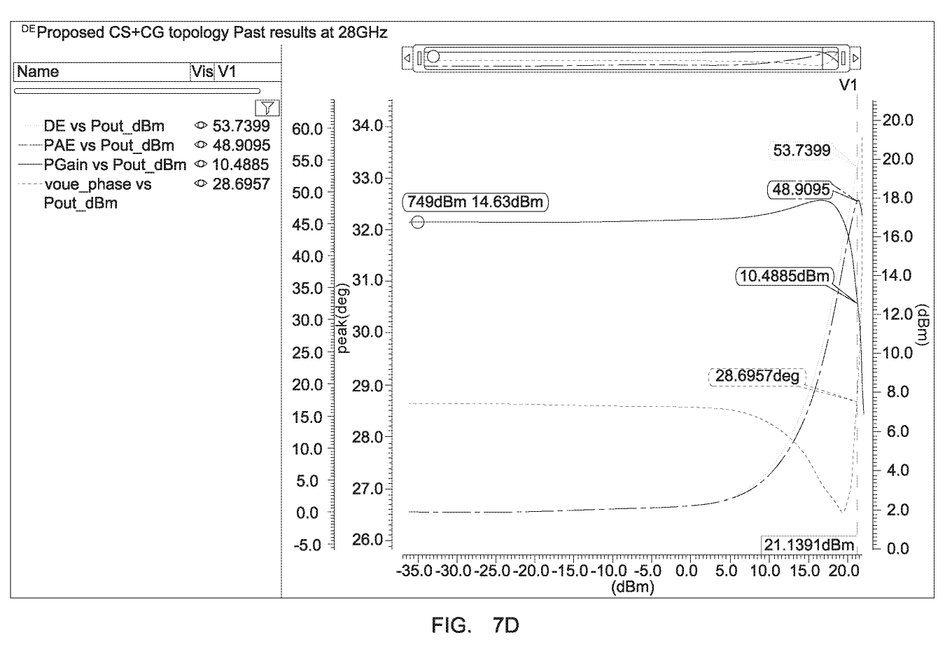

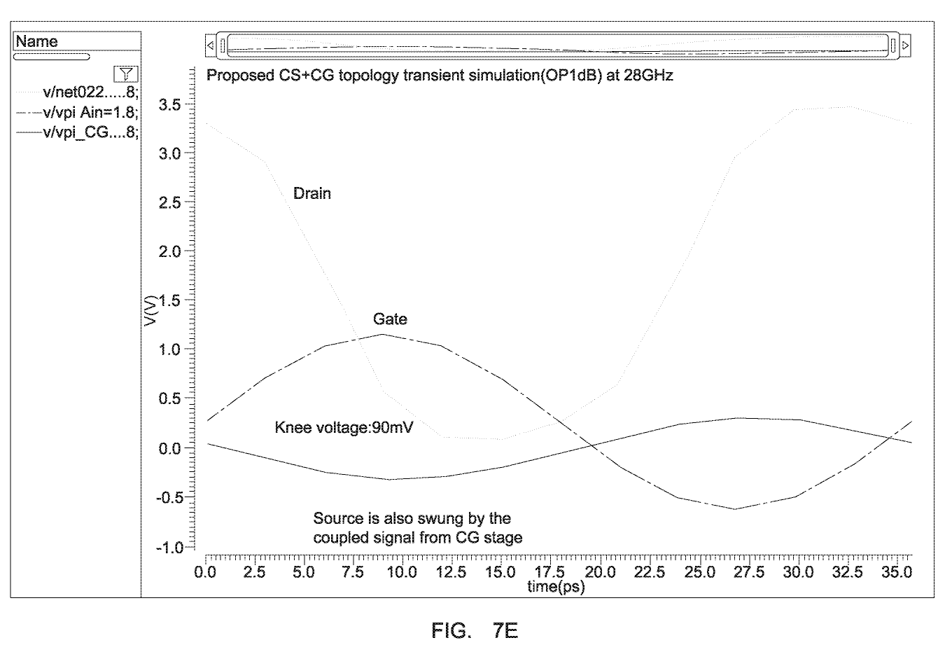

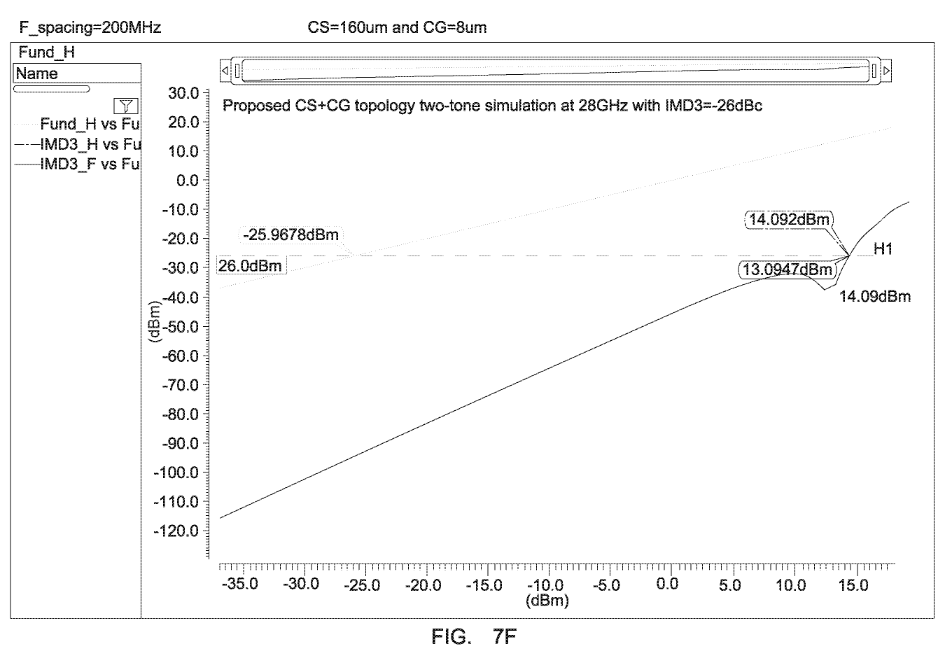

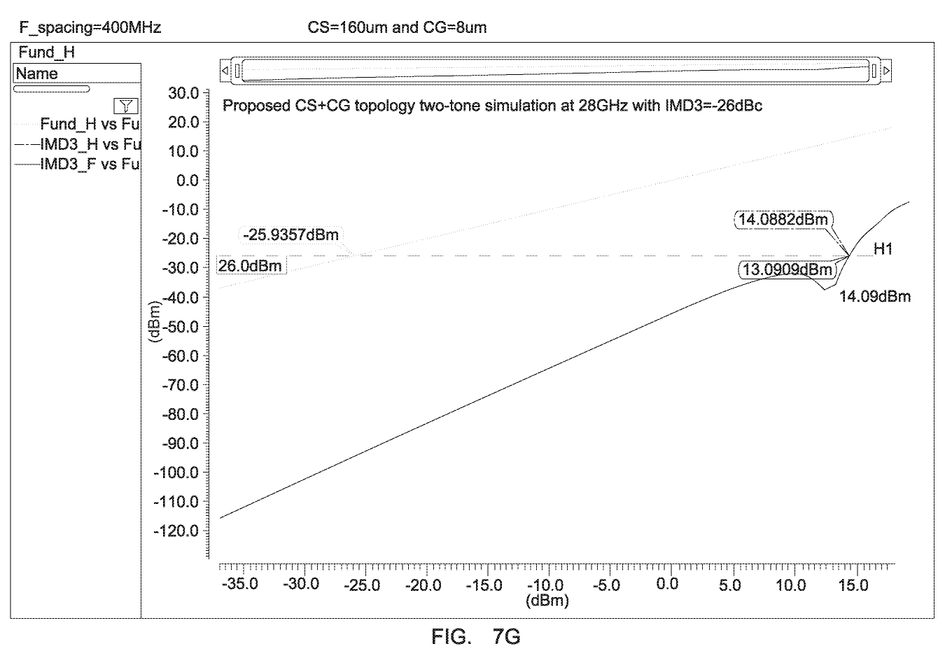

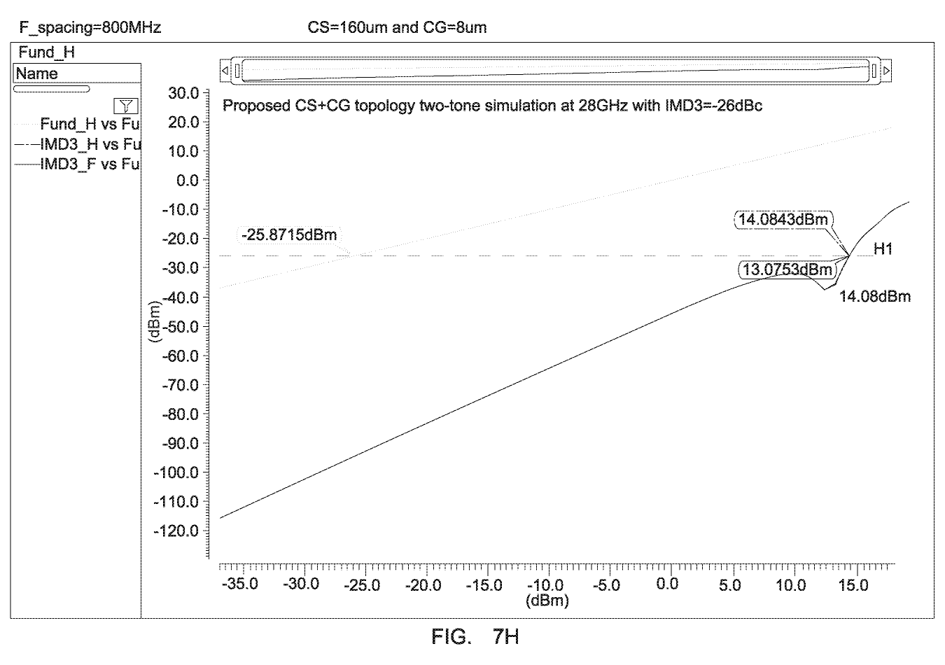

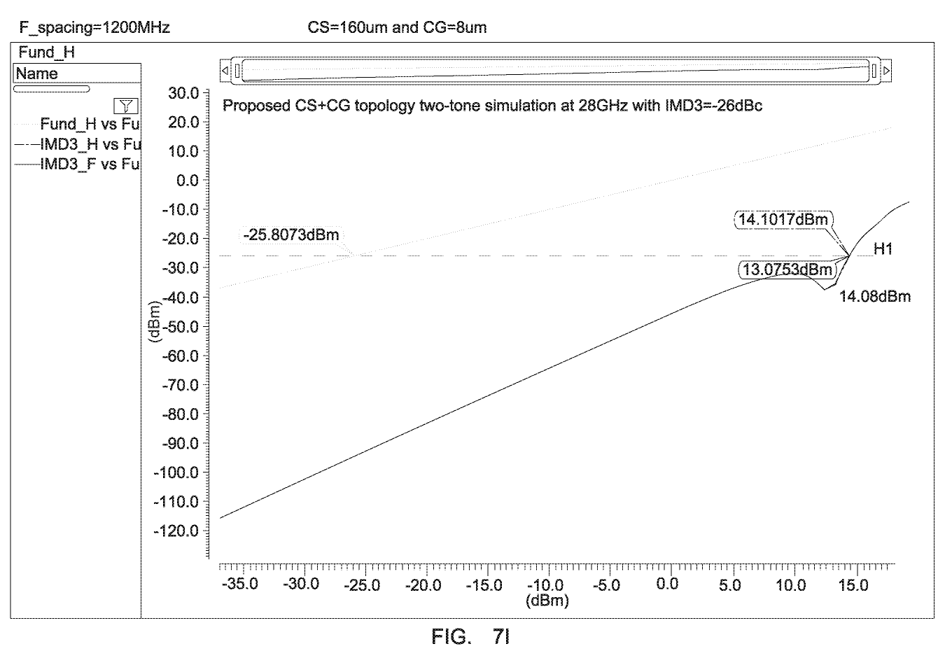

Within composite amplifier core 210, the individual amplifiers (e.g., 202, 204, and 206; or, 212, 214, and 216) can be optimally designed or reconfigurable in operation by considering their sizing ratios and independent biasing conditions. For example, with reference to the parallel CS/CG composite amplifier core shown in FIG. 3A and FIG. 7A below, by properly adjusting a sizing ratio (e.g., CS: CG=2:1, indicating that a ratio of the total number of the CS amplifiers to the total number of the CG amplifiers is 2:1) in the CS/CG amplifier composite core in FIG. 7A, the amplifier composite core demonstrates the optimal RF performance (high efficiency, high gain, and limited linearity) close to the CS amplifier core topology, comparable high efficiency with respect to the CS amplifier core topology, and high linearity with respect to the CG amplifier core topology. Furthermore, biasing conditions in both CS/CG amplifier core topologies may affect the RF performance of the active core. In composite amplifier core 210, the CS biasing and the CG biasing can be independently controlled, to boost intrinsic CS and CG RF performance in different input power levels.

Consistent with some aspects of the present disclosure, the sizing ratio can be reconfigured in a digital, analog, or mixed fashion. For example, both CS and CG amplifiers can be implemented as multiple transistors in parallel, and these transistors can be turned on or turned off based on digital control codes, which thus achieves digital reconfiguration of the sizing ratio of the CS amplifiers and the CG amplifiers. In another example, both CS and CG amplifiers can be implemented as one transistor or multiple transistors in parallel, and the biasing voltages or currents of these transistors can be adjusted in analog values, which thus achieves analog reconfiguration of the sizing ratio of the CS amplifiers and the CG amplifiers.

With combined reference to FIGS. 2A-2C, composite amplifier core 210 disclosed herein may include one or more first basic amplifiers of a first type and one or more second basic amplifiers of a second type. For example, the one or more first basic amplifiers of the first type may include one or more common-source (CS) amplifiers, and the one or more second basic amplifiers of the second type may include one or more common-gate (CG) amplifiers. Or, the one or more first basic amplifiers of the first type may include one or more CS amplifiers, and the one or more second basic amplifiers of the second type may include one or more common-drain (CD) amplifiers. Or, the one or more first basic amplifiers of the first type may include one or more CG amplifiers, and the one or more second basic amplifiers of the second type may include one or more CD amplifiers.

In another example, the one or more first basic amplifiers of the first type may include one or more common-emitter (CE) amplifiers, and the one or more second basic amplifiers of the second type may include one or more common-base (CB) amplifiers. Or, the one or more first basic amplifiers of the first type may include one or more CE amplifiers, and the one or more second basic amplifiers of the second type may include one or more common-collector (CC) amplifiers. Or, the one or more first basic amplifiers of the first type may include one or more CB amplifiers, and the one or more second basic amplifiers of the second type may include one or more CC amplifiers.

A sizing ratio between the one or more first basic amplifiers and the one or more second basic amplifiers in the composite amplifier core is adjustable (e.g., the sizing ratio = (the total number of the first basic amplifiers) : (the total number of the second basic amplifiers)). In some implementations, each of the one or more first basic amplifiers and the one or more second basic amplifiers is biased with an independent biasing signal to achieve the respective biasing condition.

With combined reference to FIGS. 2A-2C, composite amplifier core 210 may further include one or more third basic amplifiers of a third type. For example, the one or more first basic amplifiers of the first type may include one or more common-source (CS) amplifiers, the one or more second basic amplifiers of the second type may include one or more common-gate (CG) amplifier, and the one or more third basic amplifiers of the third type may include one or more common-drain (CD) amplifiers. In another example, the one or more first basic amplifiers of the first type may include one or more common-emitter (CE) amplifiers, the one or more second basic amplifiers of the second type may include one or more common-base (CB) amplifiers, and the one or more third basic amplifiers of the third type may include one or more common-collector (CC) amplifiers.

A sizing ratio among the one or more first basic amplifier, the one or more second basic amplifiers, and the one or more third basic amplifiers in the composite amplifier core is also adjustable (e.g., the sizing ratio = (the total number of the first basic amplifiers) : (the total number of the second basic amplifiers) : (the total number of the third basic amplifiers)). In some implementations, each of the one or more first basic amplifiers, the one or more second basic amplifiers, and the one or more third basic amplifiers is biased with an independent biasing signal to achieve the respective biasing condition.

Consistent with some aspects of the present disclosure, an amplifier structure may include a composite amplifier core disclosed herein, and may further include one or more of an input coupling network, an inter-stage coupling network, and an output coupling network that ensure (1) independent biasing conditions of the basic amplifiers used in the composite amplifier core, (2) constructive operations of the basic amplifiers together, and (3) suppression of intrinsic performance limitations of the basic amplifiers. Each of the input coupling network, the inter-stage coupling network, and the output coupling network can include one or more passive components that are connected in series, in parallel, or in a mixed series and parallel connection. The one or more passive components may include inductors, capacitors, transformers, couplers, transmission lines, or resistors, etc. Each of the input coupling network, the inter-stage coupling network, and the output coupling network can be implemented in a nested, feedforward, feedback, or cross-coupled configuration.

FIG. 3A illustrates a block diagram of an amplifier structure 300 disclosed herein. Amplifier structure 300 may include an input coupling network 302, composite amplifier core 210, and an output coupling network 304. In some implementations, input coupling network 302 may be connected to composite amplifier core 210 and configured to provide input signals to composite amplifier core 210. For example, input coupling network 302 may be configured to match an input impedance of composite amplifier core 210 with an output impedance of a signal source (e.g., a signal source which provides a signal “In” to input coupling network 302) to maximize the excitation power of composite amplifier core 210. Output coupling network 304 may be connected to composite amplifier core 210 and configured to adjust output signals of composite amplifier core 210 or provide the output signals of composite amplifier core 210 as “Out” signals shown in FIG. 3A. For example, output coupling network 304 may be configured to convert an external load impedance to an optimal load impedance of composite amplifier core 210 (e.g., converting an external load resistor to an optimal load resistance of composite amplifier core 210) to achieve a maximal output power.

FIG. 3B illustrates an implementation 350 of amplifier structure 300 in a power amplifier (PA), where a topology with CS/CG combination is used in composite amplifier core 210 for optimized performance in the power amplifier. For example, composite amplifier core 210 shown in FIG. 3B may include (1) one or more CS amplifiers 202 and (2) one or more CG amplifiers 204.

FIG. 3C illustrates a detailed schematic diagram 370 of implementation 350 of FIG. 3B. Input coupling network 302 may include one or more passive components 372, e.g., including at least one of a resistor, a capacitor, an inductor, a transformer, a coupler, or a transmission line. Output coupling network 304 may include one or more passive components 374, e.g., including at least one of a resistor, a capacitor, an inductor, a transformer, a coupler, or a transmission line.

As shown in FIG. 3C, composite amplifier core 210 may include two CS amplifiers 202 and two CG amplifiers 204. Composite amplifier core 210 may combine CS amplifiers 202 and CG amplifiers 204 in parallel, in series, or in a cascode manner, with each amplifier 202 or 204 having one or more transistors. CS amplifiers 202 and CG amplifiers 204 can be coupled at their inputs, outputs, and inter-stage interfaces through coupling networks. Together, the resulting composite amplifier core 210 can be used as a power amplifier (PA) to achieve linear, wideband and energy-efficient power amplification performance as well as performance robustness against load VSWR mismatches, while maintaining a sufficient gain and gain control.

Consistent with some aspects of the present disclosure, composite amplifier core 210 disclosed herein blends the principles of common-source, common drain and common-gate amplifier topologies. Taking the power amplifiers (PAs) and linear drivers as an application example. The common-source (CS) amplifier has high efficiency, intrinsic gain, and reasonable linearity. However, the common-gate amplifier (CG) excels in providing high linearity, favorable input matching qualities, and moderate efficiency and gain. Further, the common-drain (CD) amplifier provides wideband output matching with high linear power performance. Through input coupling network 302 and output coupling network 304 disclosed herein, composite amplifier core 210 can combine two or more of these basic amplifier cores together, to achieve performance attributes beyond any CS, CG, and CD amplifier cores alone.

Consistent with some aspects of the present disclosure, this integration of the common-source, common-drain and common-gate topologies into composite amplifier core 210 is achieved through various design considerations. Adjusting the sizing ratio between the common-source, common-drain and common-gate amplifiers allows us to harness the optimal characteristics of each topology for an overall balanced and optimized performance profile of energy efficiency, gain control, linearity, and input/output matching. The performance of composite amplifier core 210 can be further fine-tuned to meet specific application requirements.

Furthermore, the approach to amplifier design disclosed herein offers dynamic adaptability. For example, after composite amplifier core 210 is deployed in a circuit or system, by making adjustments to the biasing conditions or enabling different number of turned-on or turned-off transistors (e.g., adjusting the sizing ratio), the behaviors, functionalities, and performance of composite amplifier core 210 can be reconfigured to meet different application scenarios on demand or even on the fly.

In addition, the approach to amplifier design disclosed herein offers an enhanced or a better matched output reflection coefficient, S₂₂, which allows the resulting power amplifier to maintain robust RF performance, such as large-signal power gain, large-signal output phase, linearity, OP1dB, saturated output power, and energy efficiency, over the amplifier load VSWR mismatches. This is useful for various applications where amplifier loads may change or be mismatched, including applications with single amplifiers, multiple amplifiers, or arrays of amplifiers for phased arrays or Multiple-Input-Multiple-Output (MIMO) arrays. These applications include but are not limited to mobile phones, base stations, backhaul systems, radars, imaging systems, and all satellite communications.

Consistent with some aspects of the present disclosure, independent control on CS/CG amplifiers in composite amplifier core 210 of FIG. 3C is provided. For example, the biasing of CS amplifier 202 can be decreased while the biasing of CG amplifier 204 can be increased in the small signal region. The RF performance of composite amplifier core 210 is dominated by CG amplifier 204 in the small signal region with high linearity. Along with higher input power, the biasing in the CS amplifier 202 can be automatically increased and composite amplifier core 210 can demonstrate properties of the CS amplifier core topology at saturation power regions such as high efficiency and high output power. This biasing adjustment based on input power levels can be achieved by dynamic biasing circuits. Therefore, with the independent control capabilities in both CS and CG amplifiers, composite amplifier core 210 can demonstrate optimal performance at any or dynamically varying input power level (like in the actual modulation applications).

FIG. 3D illustrates amplifier structure 300 including composite amplifier core 210 that may include a CS amplifier 202 and a CG amplifier 204 in a single-ended cascode configuration. Composite amplifier core 210 may further include an inter-stage coupling network 375. CS amplifier 202 and CG amplifier 204 are connected by one or more coupling networks, including input coupling network 302, output coupling network 304, and inter-stage coupling network 375. The coupling networks 302, 304, 375 may include passive elements such as inductors, capacitors, transformers, couplers, resistors, transmission lines or any combination thereof. The passive elements may be connected in series, in parallel, or in a mixed series and parallel configuration.

FIG. 3E illustrates amplifier structure 300 including composite amplifier core 210 that may include CS amplifiers 202 and CG amplifiers 204 in a differential cascode configuration. Composite amplifier core 210 may further include inter-stage coupling network 375. Like FIG. 3D, CS amplifiers 202 and CG amplifiers 204 are connected by one or more coupling networks, including input coupling network 302, output coupling network 304, and inter-stage coupling network 375. The coupling networks 302, 304, 375 may include passive elements such as inductors, capacitors, transformers, couplers, resistors, transmission lines, or any combination thereof. The passive elements may be connected in series, in parallel, or in a mixed series and parallel configuration. Further, one or more of the coupling networks 302, 304, 375 can be cross-coupled between differential CS amplifiers 202 and differential CG amplifiers 204.

FIG. 3F illustrates amplifier structure 300 including composite amplifier core 210 that may include CS amplifiers 202 and CG amplifiers 204 in a differential cascode configuration. Like FIGS. 3D or 3E, CS amplifiers 202 and CG amplifiers 204 are connected by one or more coupling networks, including input coupling network 302, output coupling network 304, and inter-stage coupling network 375. Input coupling network 302 can be implemented as a pair of cross-coupled capacitors. Alternatively, input coupling network 302 can be removed (e.g., omitted) from amplifier structure 300. Inter-stage coupling network 375 can be implemented as a pair of series inductors. In some implementations, output coupling network 304 and inter-stage coupling network 375 may be coupled to one another, as shown by a coupling 376 in FIG. 3F. For example, output coupling network 304 can be implemented as a pair of cross-coupled capacitors in a feedback and nested fashion, i.e., each cross-coupled capacitor connects the drain node for one side of the differential CG amplifier 204 and the drain node for the opposite side of the differential CS amplifier 202.

With reference to the differential cascode CS/CG composite amplifier core shown in FIG. 3F, by properly adjusting a sizing ratio (CS: CG=M:1) in the CS/CG composite amplifier core, the output cross-coupled capacitors in output coupling network 304, and the series coupled inductors in inter-stage coupling network 375 in FIG. 3F, the composite amplifier core demonstrates the optimal RF performance (high efficiency, high gain, and limited linearity) close to a conventional cascode topology. M is a positive number. The composite amplifier core disclosed herein demonstrates a better matched output reflection coefficient of the PA, i.e., S₂₂, when compared to a conventional cascode amplifier or a CS amplifier. As a result, this example differential cascode CS/CG composite amplifier core can exhibit more robust performance, such as large-signal power gain, large-signal output phase, linearity, OP1dB, saturated output power, and energy efficiency, against load impedance mismatches or load VSWR variations.

Furthermore, biasing conditions in both CS/CG topologies may affect the RF performance of the active core. The CS biasing and CG biasing in the composite amplifier core can be independently controlled to boost intrinsic CS and CG RF performance in different input power levels.

FIG. 3G illustrates amplifier structure 300 including composite amplifier core 210 in a differential cascode configuration with a coupling 377 between input coupling network 302 and inter-stage coupling network 375, according to some aspects of the present disclosure. FIG. 3H illustrates amplifier structure 300 including composite amplifier core 210 in a differential cascode configuration with coupling 377 between input coupling network 302 and inter-stage coupling network 375 and coupling 376 between inter-stage coupling network 375 and output coupling network 304, according to some aspects of the present disclosure. As shown by FIGS. 3F-3H, input coupling network 302, inter-stage coupling network 375, and output coupling network 304 may be coupled to one another.

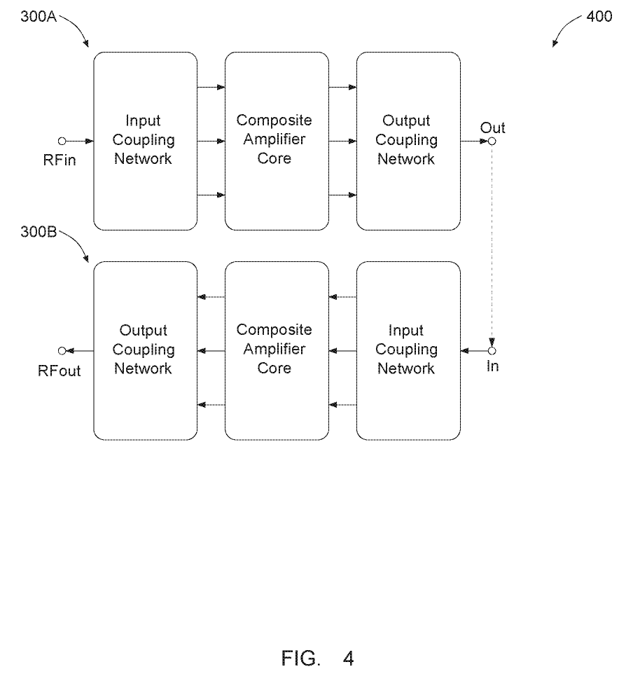

This composite amplifier core technique disclosed herein can be applied in various mixed-signal, analog, and RF circuit applications, including drivers, power amplifiers (PAs), distributed amplifiers, low-noise amplifiers (LNAs), mixers, and oscillators, and so on. FIG. 4 illustrates a circuit structure 400 which includes two amplifier structures 300 (300A, 300B). Each amplifier structure 300 can be used for a PA, LNA, driver amplifier, or distributed amplifier, etc. Amplifier structures 300 can be cascaded. For example, amplifier structure 300A can be cascaded with amplifier structure 300B.

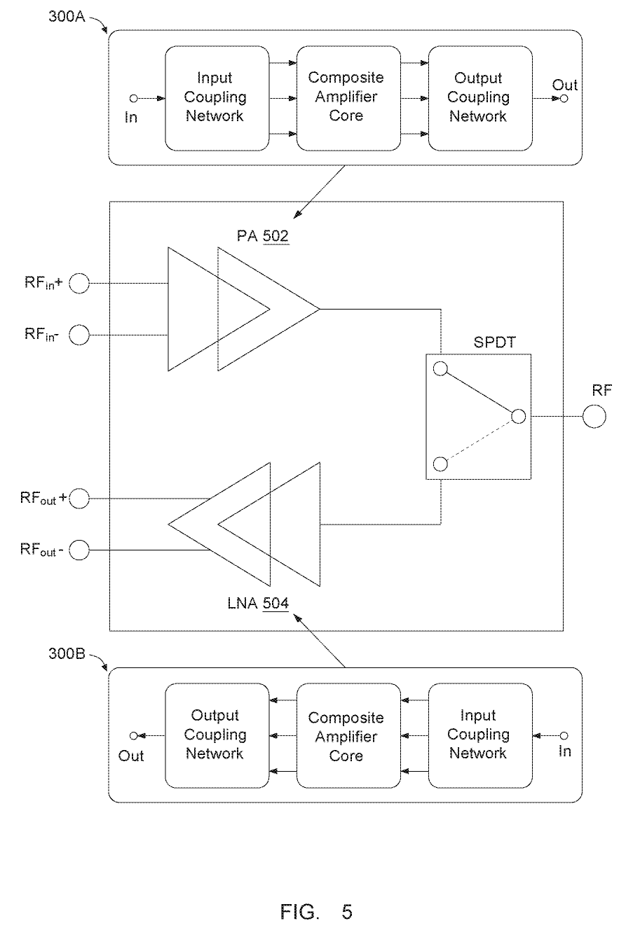

FIG. 5 illustrates an implementation of circuit structure 400 in RF/mm-Wave system applications. For example, amplifier structure 300A can be used to implement a power amplifier 502, and amplifier structure 300B can be used implement a low noise amplifier 504.

Example applications of composite amplifier core 210, amplifier structure 300, and circuit structure 400 may include, but are not limited to, Telecommunication, Satellite communication, radar, imaging, electronic warfare, wireless power transfer, AI-Assisted system, and directed energy system.

Composite amplifier core 210, amplifier structure 300, and circuit structure 400 disclosed herein offer a range of advantages. This combined topology disclosed herein allows for the creation of new classes of amplifiers with varying common source/common gate/common drain ratios, resulting in performance enhancements, e.g., in terms of linearity, efficiency, input matching, bandwidth, and gain, as well as performance robustness against load VSWR variations or mismatches, beyond the basic amplifier cores that the composite amplifier core is based on. Moreover, composite amplifier core 210, amplifier structure 300, and circuit structure 400 disclosed herein can be optimized and easily customized for different performance targets. Further, composite amplifier core 210, amplifier structure 300, and circuit structure 400 disclosed herein can be reconfigured after being deployed in a physical circuits or systems for in-field or on-the-fly performance improvement and even circuit topological or functional reconfiguration.

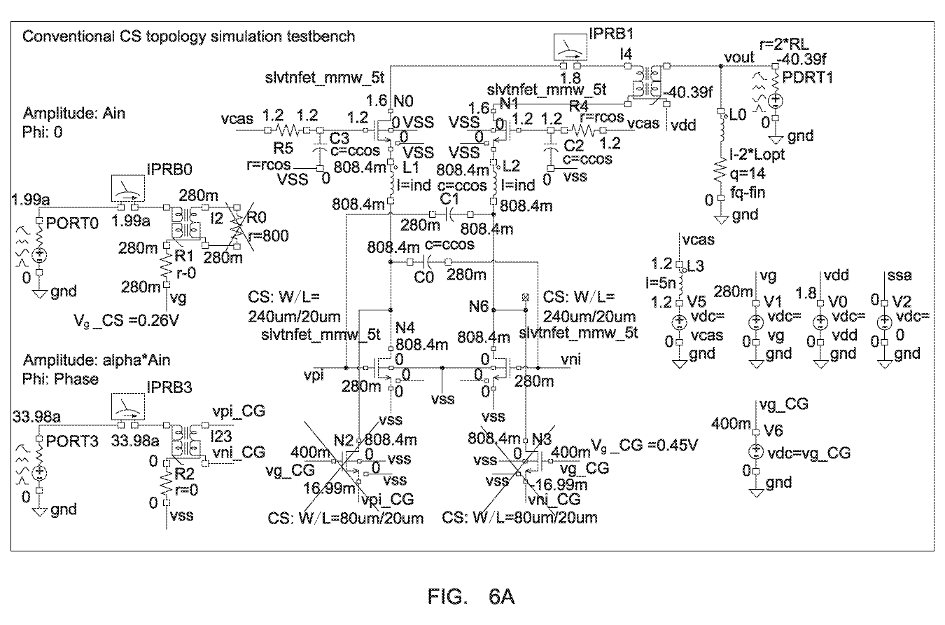

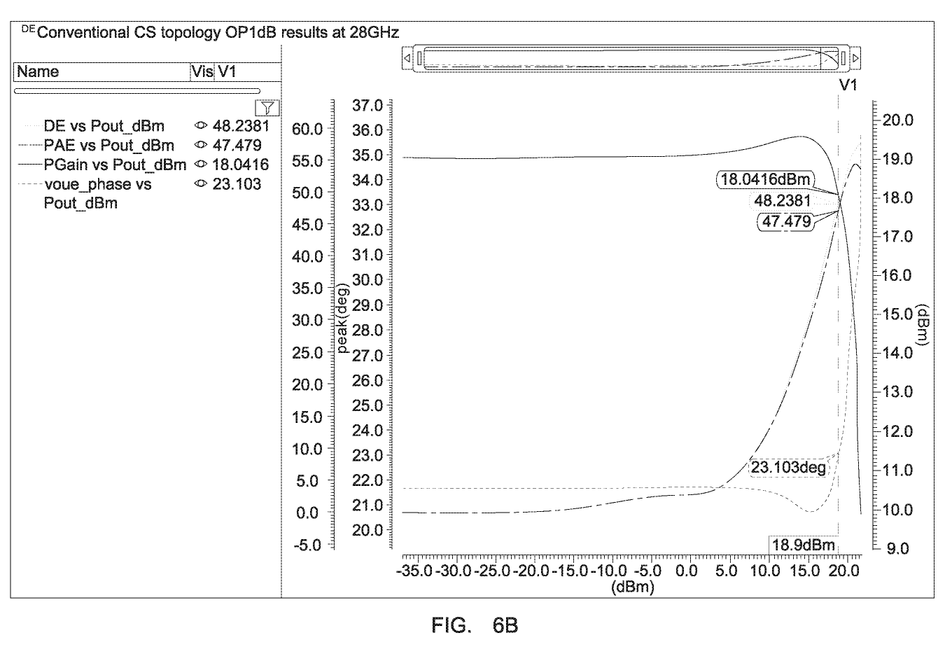

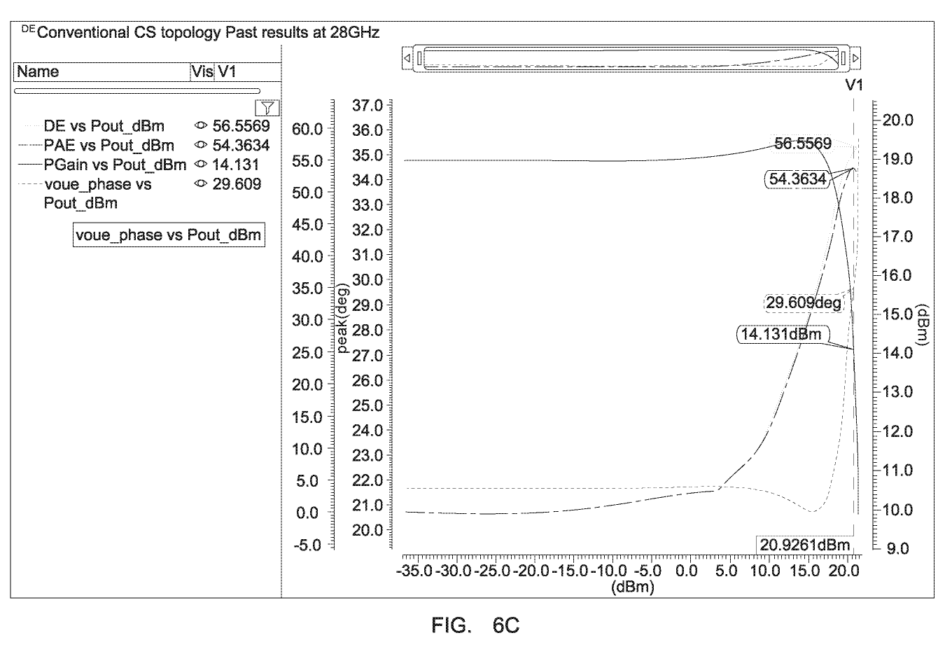

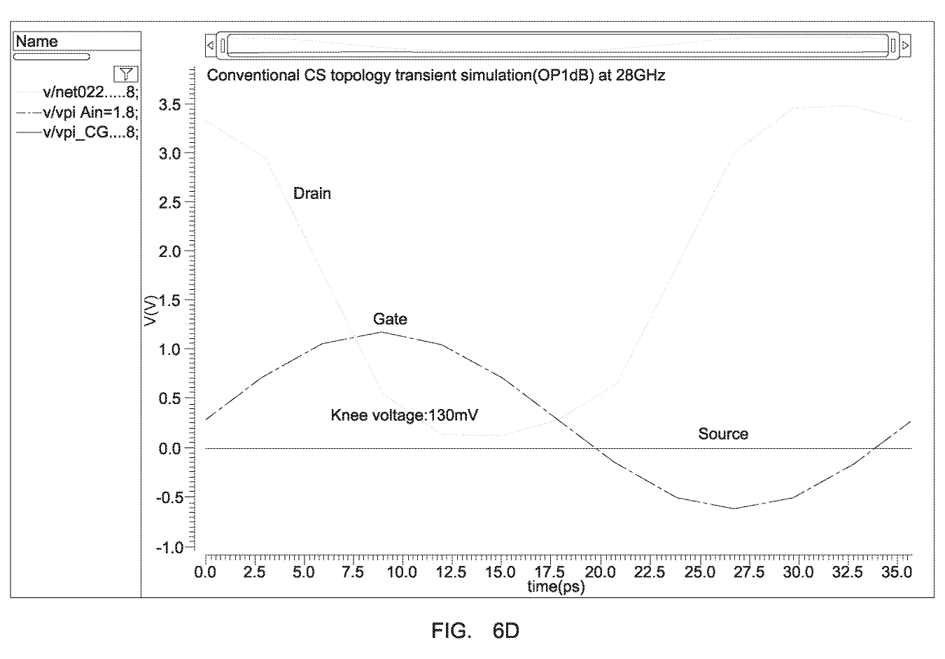

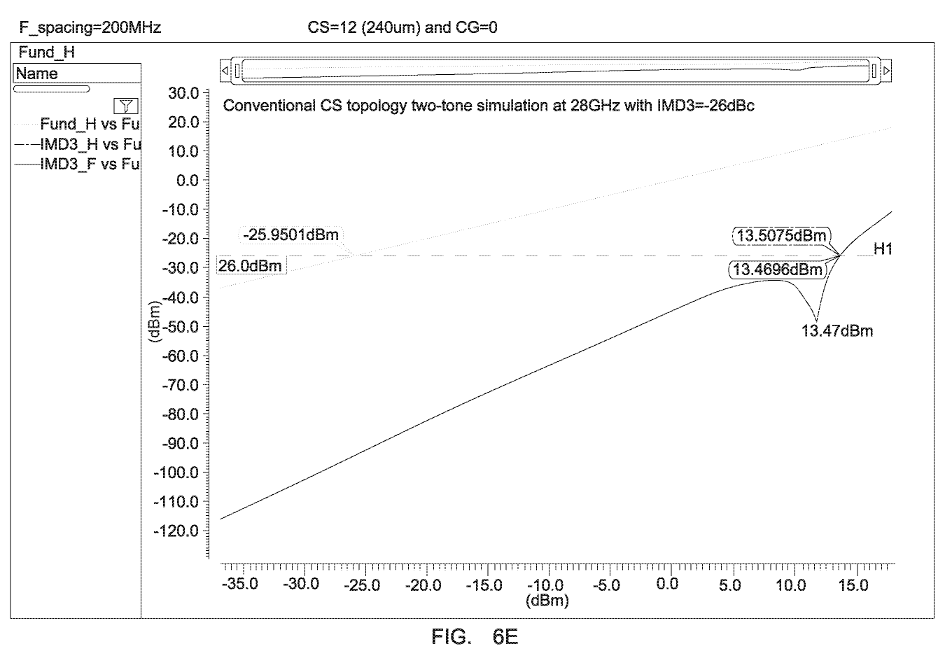

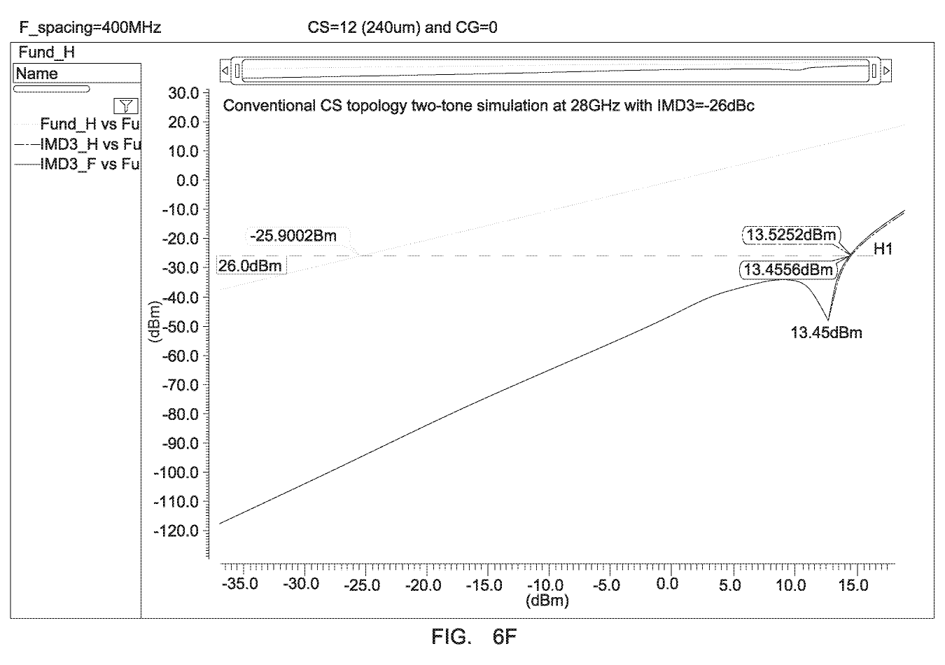

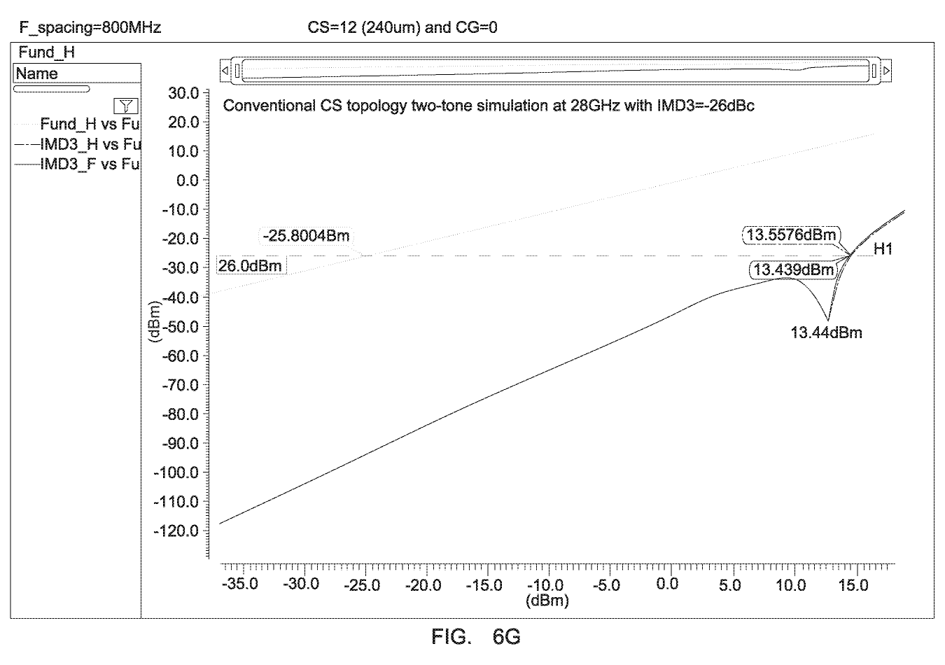

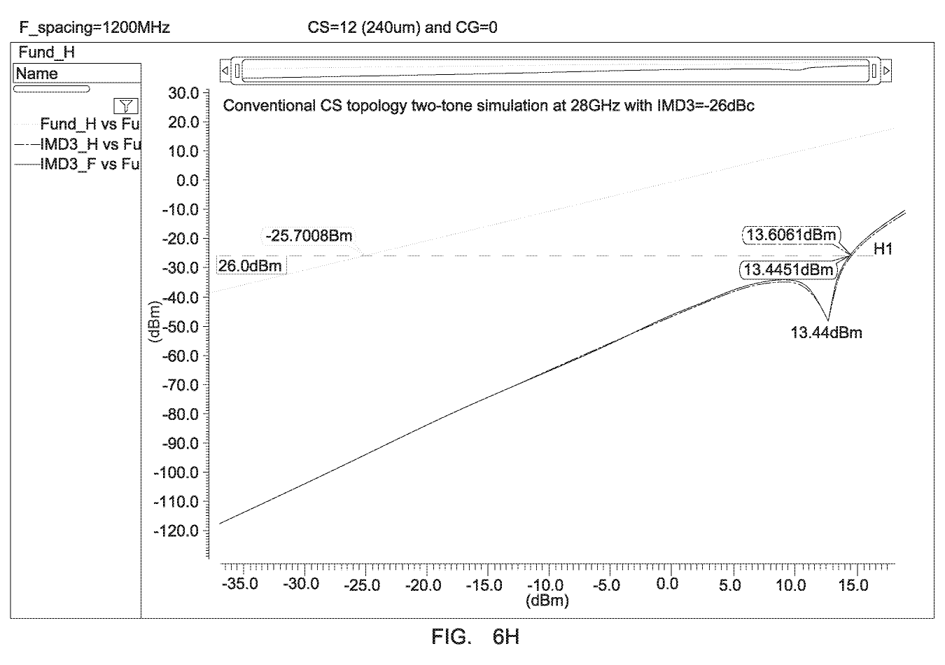

FIGS. 6A-6H illustrate simulation on an example common-source (CS) PA, according to some examples. FIGS. 7A-7I illustrate simulation on an example PA disclosed herein (e.g., the PA of FIGS. 3B or 3C) with integration of the common-source(CS) amplifiers and common-gate(CG) amplifiers, according to some aspects of the present disclosure.

In some implementations, linear power OP1dB can achieve a 1.3dB improvement in the PA disclosed herein (FIGS. 7A-7I) compared to the example common-source PA (FIGS. 6A-6H). AM/PM can be controlled within 3-degree till saturation power level (the example common-source PA of FIGS. 6A-6H with 8.6 degree). The ratio in CS and CG topology of composite amplifier core 210 can be determined for high gain, high linear power, or linear efficiency. Composite amplifier core 210 may include both CS amplifiers 202 and CG amplifiers 204. Alternatively, composite amplifier core 210 may include both CS amplifiers 202 and CD amplifiers 206. Alternatively, composite amplifier core 210 may include both CG amplifiers 204 and CD amplifiers 206.

As used herein, in AM/PM Conversion (Phase Distortion), AM stands for Amplitude Modulation, but refers to how variations in the input signal’s amplitude affect the output signal’s phase. In other words, it’s the change in the phase angle of the output signal as a function of the input power level. If the phase of the output signal remains constant as you vary the input power, there is no AM/PM conversion, and the amplifier preserves the signal’s phase. If the phase of the output signal changes with variations in input power, this is referred to as AM/PM conversion or phase distortion. Phase distortion can manifest in various ways, including shifting or modulation of the signal’s phase. In practice, power amplifiers exhibit an AM/PM response, which may be monotonically increasing, monotonically decreasing, or non-monotonic. In general, AM/PM conversion becomes more pronounced at higher input drive levels, approaching gain compression.

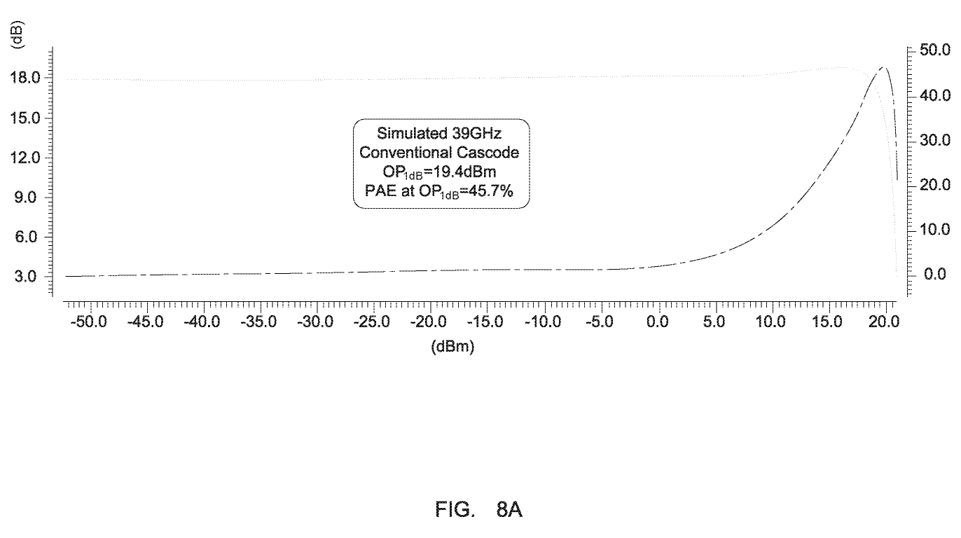

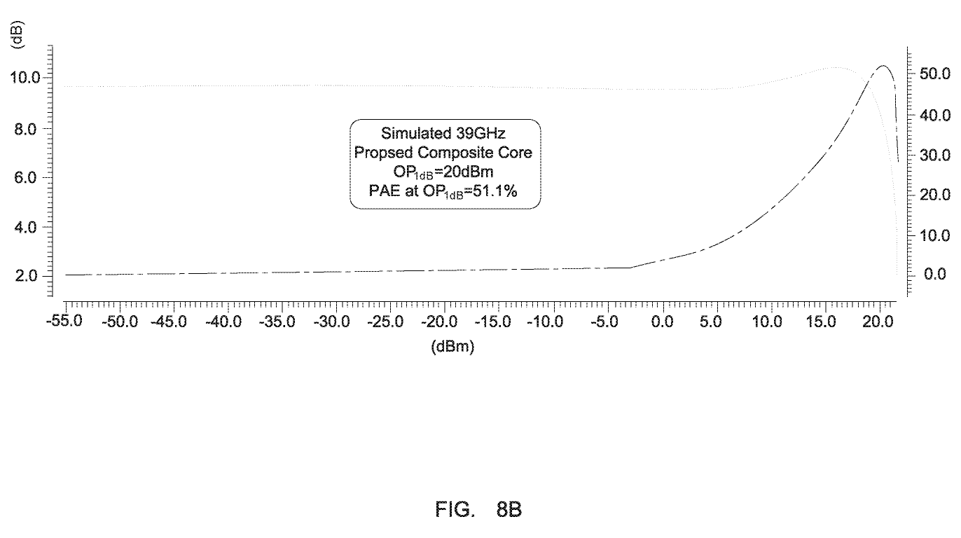

FIG. 8A illustrates simulation on a conventional differential amplifier core in a cascode configuration at 39GHz, according to some examples. FIG. 8B illustrates a load pull simulation of a composite amplifier core at 39GHz, according to some aspects of the present disclosure.

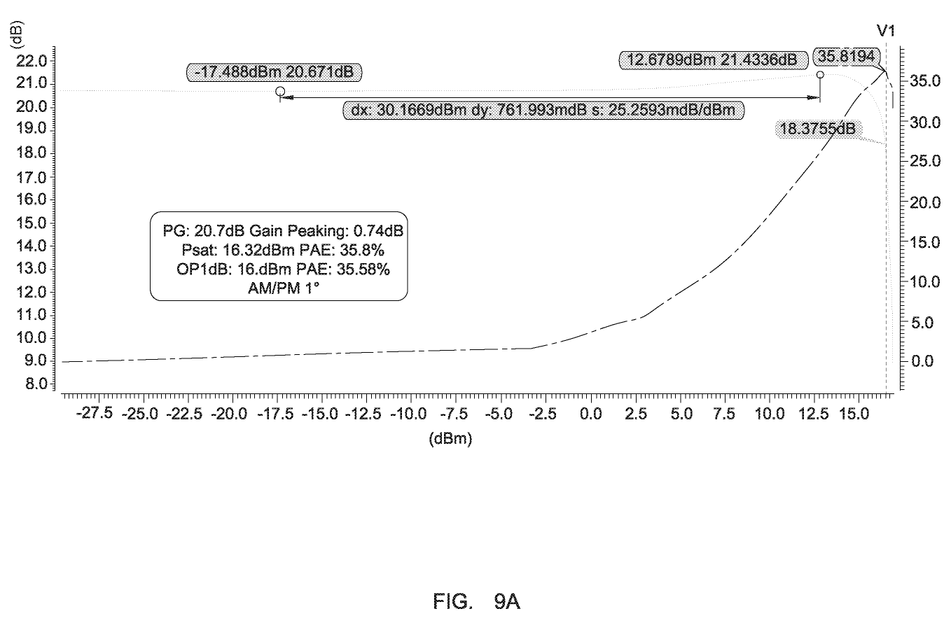

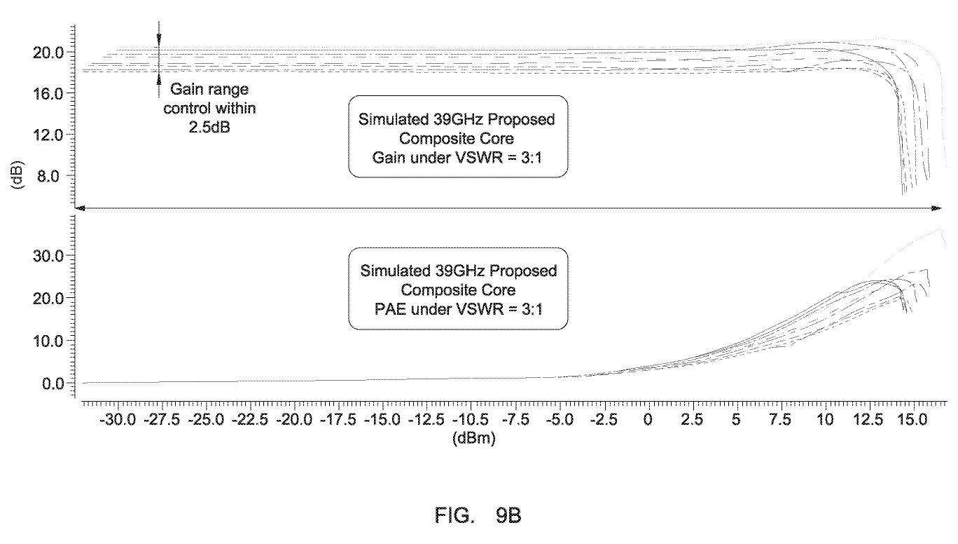

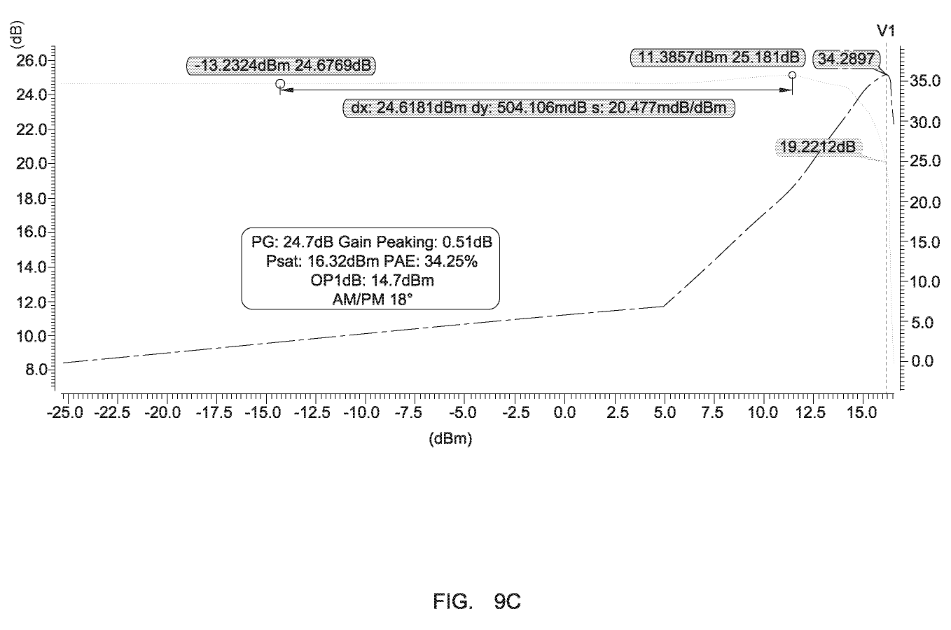

FIG. 9A illustrates a continuous wave simulation of a composite amplifier core at 39GHz, according to some aspects of the present disclosure. FIG. 9B illustrates a continuous wave simulation of a composite amplifier core at 39GHz under VSWR 3-to-1, according to some aspects of the present disclosure. FIG. 9C illustrates a continuous wave simulation of a common source amplifier core at 39GHz, according to some aspects of the present disclosure.

In FIGS. 9A-9C, the composite amplifier core can be implemented in a power amplifier (PA) and referred to as a composite PA core, with integration of the common-source (CS) amplifiers and common-gate (CG) amplifiers in a differential cascode configuration. The composite PA core may include first basic amplifiers (e.g., differential CS amplifiers), second basic amplifiers (e.g., differential CG amplifiers), and an inter-stage coupling network coupled to the first basic amplifiers and the second basic amplifiers. An amplifier structure may include the composite PA core, an input coupling network, and an output coupling network.

In some implementations, the composite amplifier core with combined common-source and common-gate topologies in the cascode configuration can be applied herein. In some implementations, linear power OP1dB can achieve a 1.3dB improvement in the PA disclosed herein compared to a conventional common-source PA. AM/PM can be controlled within 3-degree till saturation power level (conventional common-source PA with 17 degree). The ratio in CS and CG topology of the composite amplifier core can be determined for high gain, high linear power, or linear efficiency. This composite amplifier core with a combination of CS and CG topologies can be extended to a combination of CS and CD topologies or a combination of CG and CD topologies.

In some implementations, a method for amplifier design is disclosed, which includes integrating common-source, common-drain, and common-gate amplifier topologies in a specified sizing ratio to achieve enhanced performance characteristics, including linearity, efficiency, noise, input matching, output matching, bandwidth, and gain.

In some implementations, an amplifier structure is disclosed for applications such as low-noise amplifier, driver amplifier, distributed amplifier, mixers, oscillators, and so on. The amplifier structure includes a composite amplifier core including a combination of common-source, common-drain, and common-gate amplifier elements, with adjustability in relative sizing to optimize performance attributes including linearity, efficiency, noise, input matching, output matching, bandwidth, and gain. The amplifier structure further includes an input coupling network and an output coupling network which are coupled to the composite amplifier core.

In some implementations, a circuit structure for customizable amplifier performance is disclosed. The circuit structure includes one or more amplifier structures each designed with a hybrid common-source, common-drain, and common-gate topology, allowing configurable sizing ratios of these components to achieve desired characteristics, including linearity, efficiency, noise, input matching, output matching, bandwidth, and gain.

In some implementations, a circuit structure for customizable amplifier performance is disclosed. The circuit structure includes one or more amplifier structures each designed with a hybrid common-source, common-drain, and common-gate topology, allowing reconfigurable topologies and/or functionalities, such as amplification, attenuation, input/output phase shifts, input/output power levels, matching, operation frequency.

In some implementations, devices implementing a composite amplifier core or other circuit components may include CMOS devices, Bipolar junction transistor devices, Gallium Nitride devices, Gallium Arsenide devices, carbon nanotubes, graphene devices, or combinations thereof.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A composite amplifier core, comprising:
one or more first basic amplifiers of a first type; and
one or more second basic amplifiers of a second type,
wherein a sizing ratio between the one or more first basic amplifiers and the one or more second basic amplifiers in the composite amplifier core is adjustable.

2. The composite amplifier core according to claim 1, wherein each of the one or more first basic amplifiers and the one or more second basic amplifiers is biased with an independent biasing signal.

3. The composite amplifier core according to claim 1, wherein:
the one or more first basic amplifiers of the first type comprise one or more common-source (CS) amplifiers, and the one or more second basic amplifiers of the second type comprise one or more common-gate (CG) amplifiers; or
the one or more first basic amplifiers of the first type comprise one or more CS amplifiers, and the one or more second basic amplifiers of the second type comprise one or more common-drain (CD) amplifiers; or
the one or more first basic amplifiers of the first type comprise one or more CG amplifiers, and the one or more second basic amplifiers of the second type comprise one or more CD amplifiers.

4. The composite amplifier core according to claim 1, wherein:
the one or more first basic amplifiers of the first type comprise one or more common-emitter (CE) amplifiers, and the one or more second basic amplifiers of the second type comprise one or more common-base (CB) amplifiers; or
the one or more first basic amplifiers of the first type comprise one or more CE amplifiers, and the one or more second basic amplifiers of the second type comprise one or more common-collector (CC) amplifiers; or
the one or more first basic amplifiers of the first type comprise one or more CB amplifiers, and the one or more second basic amplifiers of the second type comprise one or more CC amplifiers.

5. The composite amplifier core according to claim 1, wherein the one or more first basic amplifiers and the one or more second basic amplifiers are connected in parallel, in series, or in a mixed parallel and series configuration.

6. The composite amplifier core according to claim 1, wherein the one or more first basic amplifiers and the one or more second basic amplifiers are in a cascode configuration, a single-ended configuration, or a differential configuration.

7. The composite amplifier core according to claim 1, further comprising an inter-stage coupling network coupled between the one or more first basic amplifiers and the one or more second basic amplifiers.

8. An amplifier structure, comprising:
a composite amplifier core comprising:
one or more first basic amplifiers of a first type; and
one or more second basic amplifiers of a second type,
wherein a sizing ratio between the one or more first basic amplifiers and the one or more second basic amplifiers in the composite amplifier core is adjustable; and
an output coupling network connected to the composite amplifier core and configured to provide output signals of the composite amplifier core.

9. The amplifier structure according to claim 8, further comprising an input coupling network connected to the composite amplifier core and configured to match an input impedance of the composite amplifier core with an output impedance of a signal source.

10. The amplifier structure according to claim 8, wherein the output coupling network has a nested feedback configuration.

11. The amplifier structure according to claim 9, wherein the composite amplifier core further comprises an inter-stage coupling network coupled between the one or more first basic amplifiers and the one or more second basic amplifiers.

12. The amplifier structure according to claim 11, wherein each of the input coupling network, the inter-stage coupling network, and the output coupling network comprises one or more passive components comprising at least one of a resistor, a capacitor, an inductor, a transformer, a coupler, or a transmission line.

13. The amplifier structure according to claim 11, wherein the input coupling network, the inter-stage coupling network, and the output coupling network are coupled with each other.

14. The amplifier structure according to claim 8, wherein each of the one or more first basic amplifiers and the one or more second basic amplifiers is biased with an independent biasing signal.

15. The amplifier structure according to claim 8, wherein the one or more first basic amplifiers and the one or more second basic amplifiers are connected in parallel, in series, or in a mixed parallel and series configuration.

16. The amplifier structure according to claim 8, wherein the one or more first basic amplifiers and the one or more second basic amplifiers are in a cascode configuration, a single-ended configuration, or a differential configuration.

17. The amplifier structure according to claim 8, wherein:
the one or more first basic amplifiers of the first type comprise one or more common-source (CS) amplifiers, and the one or more second basic amplifiers of the second type comprise one or more common-gate (CG) amplifiers; or
the one or more first basic amplifiers of the first type comprise one or more CS amplifiers, and the one or more second basic amplifiers of the second type comprise one or more common-drain (CD) amplifiers; or
the one or more first basic amplifiers of the first type comprise one or more CG amplifiers, and the one or more second basic amplifiers of the second type comprise one or more CD amplifiers.

18. The amplifier structure according to claim 8, wherein:
the one or more first basic amplifiers of the first type comprise one or more common-emitter (CE) amplifiers, and the one or more second basic amplifiers of the second type comprise one or more common-base (CB) amplifiers; or
the one or more first basic amplifiers of the first type comprise one or more CE amplifiers, and the one or more second basic amplifiers of the second type comprise one or more common-collector (CC) amplifiers; or
the one or more first basic amplifiers of the first type comprise one or more CB amplifiers, and the one or more second basic amplifiers of the second type comprise one or more CC amplifiers.

19. A circuit structure, comprising:
a first amplifier structure; and
a second amplifier structure cascaded with the first amplifier structure,
wherein each of the first amplifier structure and the second amplifier structure comprises:
a composite amplifier core comprising:
one or more first basic amplifiers of a first type; and
one or more second basic amplifiers of a second type,
wherein a sizing ratio between the one or more first basic amplifiers and the one or more second basic amplifiers in the composite amplifier core is adjustable;
an input coupling network connected to the composite amplifier core and configured to provide input signals to the composite amplifier core; and
an output coupling network connected to the composite amplifier core and configured to provide output signals of the composite amplifier core.

20. The circuit structure according to claim 19, wherein the composite amplifier core further comprises an inter-stage coupling network coupled between the one or more first basic amplifiers and the one or more second basic amplifiers.
